(19) United States
(12) Patent Application Publication
(10) Pub. No.: US 2025/0377173 A1
(43) Pub. Date: Dec. 11, 2025

(54) LIQUID-COOLING HEAT DISSIPATION DEVICE

(71) Applicant: ALPHA NETWORKS INC., Hsinchu (TW)

(72) Inventors: CHIH-KUANG WANG, Hsinchu (TW); SHAO-KANG LIU, Hsinchu (TW); DONG-FU CHEN, Hsinchu (TW)

(73) Assignee: ALPHA NETWORKS INC., Hsinchu (TW)

(21) Appl. No.: 18/917,438

(22) Filed: Oct. 16, 2024

(30) Foreign Application Priority Data
Jun. 5, 2024 (TW) 113120872

(51) Int. Cl. F28F 3/02

(52) U.S. Cl. CPC F28F 3/02; F28F 2215/00

(57) ABSTRACT

A liquid-cooling heat dissipation device includes a case having a chamber. At least one cooling fin is disposed in the chamber. A bottom case has at least one opening matching a number of the at least one cooling fin. The at least one cooling fin has a thermal bump protruding from the opening. A side of a periphery of the thermal bump has a guiding portion. A first seal ring is disposed between the cooling fin and a periphery of the opening. An elastic assembly which drives the at least one cooling fin to return to an original position after moving is disposed on the bottom case. When the present invention is used, the case is connected to a liquid pipeline for heat dissipation and the thermal bump of the at least one cooling fin contacts a heat source.

### BACKGROUND OF THE INVENTION

### Technical Field

The present invention relates generally to a cooling device, and more particularly to a liquid-cooling heat dissipation device.

### Description of Related Art

When a networking switch operates for a long time, a large amount of heat might be generated during a photoelectric conversion; especially electronic communication devices such as routers and network switches. A heat dissipation function of the networking switch has strict requirements within a limited volume. If a heat dissipation requirement could not be met, the networking switch might be overheated, causing communication instability such as failure of the networking switch, data packet loss, etc.; especially between adjacent communication ports, where high heat density affects heat dissipation. In order to solve the above heat dissipation problem, a water cooling radiator is applied to an optical communication device for heat dissipation, thereby efficiently removing the heat generated by the optical communication device from the optical communication device through a liquid.

When the conventional water cooling radiator is used, a heat dissipating surface of a case of the water cooling radiator is in contact with a surface of a heat source, and the liquid flowing in the case of the water cooling radiator removes the heat conducted from the heat source. When the water cooling radiator is in use, the heat dissipating surface of the case of the water cooling radiator needs to tightly attach to the heat source for the heat of the heat source to be efficiently conducted to the water cooling radiator for heat dissipation. Due to a fixed shape of the heat dissipating surface of the water cooling radiator, when the water cooling radiator is applied to a hot swap of a small form-factor pluggable of the optical communication device, the heat dissipating surface of the water cooling radiator could not adapt to fluctuations caused by plugging the optical communication device in different small form-factor pluggable or unplugging the optical communication device from different small form-factor pluggable, so that the heat dissipating surface of the water cooling radiator could not keep attaching the small form-factor pluggable tightly and could not meet such the heat dissipation requirement.

### BRIEF SUMMARY OF THE INVENTION

In view of the above, the primary objective according to the present invention is to provide a liquid-cooling heat dissipation device provided with cooling fins that could be pushed up and return to an original position when released and correspond to individual heat sources such as small form-factor pluggable, so that each of the cooling fins is adaptable and could be tightly attached to surfaces of the heat sources, thereby providing a better heat dissipation effect.

The present invention provides a liquid-cooling heat dissipation device, including a case, at least one cooling fin, at least one first seal ring, and at least one elastic assembly. The case includes a bottom case and a top case, wherein the bottom case and the top case are connected to each other in a sealed way to form a chamber within the case; the case further has a liquid inlet and a liquid outlet; the liquid inlet and the liquid outlet communicate with the chamber respectively; the bottom case has at least one opening; the at least one opening communicates with the chamber.

The at least one cooling fin is disposed in the chamber and has a thermal bump; the thermal bump of the at least one cooling fin correspondingly passes through the at least one opening and protrudes from the bottom case; a side of a periphery of the thermal bump has a guiding portion. A side of the at least one first seal ring is in contact with the at least one cooling fin; another side of the at least one first seal ring is in contact with a periphery of the at least one opening; the at least one first seal ring seals between a periphery of the at least one cooling fin and the periphery of the at least one opening. An end of the at least one elastic assembly is fixed to the case and another end of the at least one elastic assembly is in contact with the at least one cooling fin; when the thermal bump of the at least one cooling fin is pushed and the at least one cooling fin is correspondingly moved towards the chamber to deform the at least one elastic assembly, the at least one elastic assembly generates a restoring force that correspondingly returns the at least one cooling fin to an original position.

When the present invention is used, the liquid inlet of the case and the liquid outlet of the case are connected to the liquid pipeline for heat dissipation, so that the chamber within the case is filled with the liquid for heat dissipation. The thermal bump of each of the cooling fins is in contact with the heat source. When each of the cooling fins is in contact with the liquid for heat dissipation within the case, the heat conducted by the thermal bump of each of the cooling fins through contacting the heat source could be conducted to the liquid for heat dissipation in the chamber. With a circular process that the liquid for heat dissipation flows into the case through the liquid inlet and is discharged from the case through the liquid outlet for cooling, so that the heat source contacting each of the cooling fins could be cooled down.

The thermal bump of each of the cooling fins protrudes from the opening and each of the first seal ring is disposed between the periphery of each of the cooling fins and the periphery of each of the openings in a sealed way. In this way, the case of the present invention is disposed on the sockets of the optical communication device and the thermal bump of each of the cooling fins extends into each of the sockets. Once the small form-factor pluggable is plugged into the socket, each of the cooling fins is pushed by the restoring force of each of the elastic assemblies pushing each of the cooling fins, so that the thermal bump of each of the cooling fins could be tightly attached to the surface of the small form-factor pluggable after each of the cooling fins is pushed. In this way, each of the cooling fins could adapt fluctuations caused by plugging different small form-factor pluggables into the sockets of the optical communication device or unplugging the small form-factor pluggables from the sockets of the optical communication device, so that the thermal bump of each of the cooling fins could keep attaching the small form-factor pluggable tightly, thereby achieving a good heat dissipation effect.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of the liquid-cooling heat dissipation device of a first embodiment according to the present invention;

FIG. 2 is a perspective view of the liquid-cooling heat dissipation device of the first embodiment according to the present invention seen from another perspective;

FIG. 3 is an exploded view of the liquid-cooling heat dissipation device of the first embodiment according to the present invention;

FIG. 4 is a perspective view of the cooling fin of the liquid-cooling heat dissipation device of the first embodiment according to the present invention;

FIG. 5 is a perspective view of the cooling fin of the liquid-cooling heat dissipation device of the first embodiment according to the present invention seen from another perspective;

FIG. 6 is a top view of the liquid-cooling heat dissipation device of the first embodiment according to the present invention;

FIG. 7 is a sectional schematic view along the F7-F7 line in FIG. 6;

FIG. 8 is a sectional schematic view along the F8-F8 line in FIG. 6;

FIG. 9 is a schematic view, showing the liquid-cooling heat dissipation device of the first embodiment according to the present invention is disposed on the optical communication device;

FIG. 10 is a sectional schematic view in FIG. 9, showing the small form-factor pluggable is plugged into the sockets;

FIG. 11 is a sectional schematic view in FIG. 10, showing the cooling fins are pushed up;

FIG. 12 is a perspective view of the liquid-cooling heat dissipation device of a second embodiment according to the present invention;

FIG. 13 is an exploded view of the liquid-cooling heat dissipation device of the second embodiment according to the present invention;

FIG. 14 is a perspective view of the cooling fin of the liquid-cooling heat dissipation device of the second embodiment according to the present invention seen from another perspective;

FIG. 15 is a top view of the liquid-cooling heat dissipation device of the second embodiment according to the present invention;

FIG. 16 is a sectional schematic view along the F16-F16 line in FIG. 15;

FIG. 17 is a sectional schematic view along the F17-F17 line in FIG. 15;

FIG. 18 is a perspective view of the liquid-cooling heat dissipation device of a third embodiment according to the present invention;

FIG. 19 is an exploded view of the liquid-cooling heat dissipation device of the third embodiment according to the present invention, showing the top case is disassembled from the bottom case;

FIG. 20 is a perspective view of the cooling fin of the liquid-cooling heat dissipation device of the third embodiment according to the present invention;

FIG. 21 is a perspective view of the cooling fin of the liquid-cooling heat dissipation device of the third embodiment according to the present invention seen from another perspective;

FIG. 22 is a top view of the liquid-cooling heat dissipation device of the third embodiment according to the present invention;

FIG. 23 is a sectional schematic view along the F23-F23 line in FIG. 22; and

FIG. 24 is a sectional schematic view along the F24-F24 line in FIG. 22.

### DETAILED DESCRIPTION OF THE INVENTION

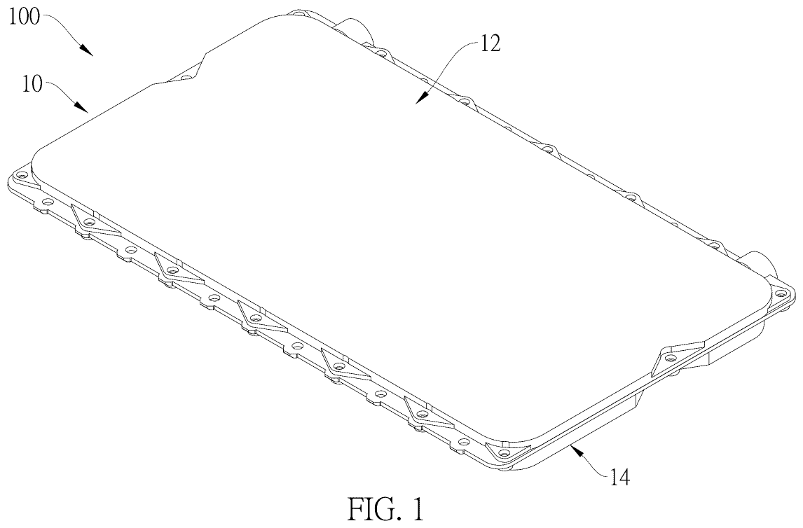

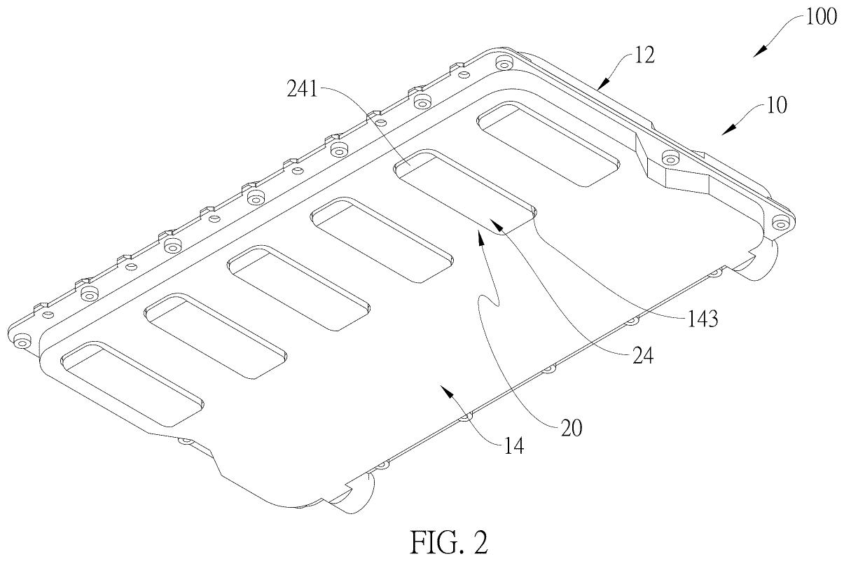

As illustrated in FIG. 1 to FIG. 6, a liquid-cooling heat dissipation device 100 of a first embodiment according to the present invention includes a case 10, six cooling fins 20, six first seal rings 30 matching the number of the cooling fins 20, and six elastic assemblies 40 matching the number of the cooling fins 20.

The case 10 is a flat shell and has a front side, a back side, a left side, a right side, a top side, a bottom side in terms of direction. The case 10 includes a top case 12 and a bottom case 14. The top case 12 and the bottom case 14 are connected to each other in a sealed way. The top case 12 is a rectangular plate and a perimeter of the top case 12 has a periphery 121. The periphery 121 of the top case 12 has a plurality of fixing holes 122 arranged around the periphery 121 of the top case 12. The bottom case 14 is a rectangular tray and a perimeter of the bottom case 14 has a periphery 141. The periphery 141 of the bottom case 14 has a plurality of fixing holes 142 arranged around the periphery 141 of the bottom case 14. The fixing holes 122 of the top case 12 and the fixing holes 142 of the bottom case 14 face each other.

A second seal ring 161 is clamped between the periphery 121 of the top case 12 and the periphery 141 of the bottom case 14. A plurality of fixing elements 18 respectively pass through the fixing holes 122 of the top case 12 on the periphery 121 of the top case 12 and the fixing holes 142 of the bottom case 14 on the periphery 141 of the bottom case 14 to connect the top case 12 with the bottom case 14 in a sealed way, thereby forming a chamber 16 within the case 10. In other embodiments, the top case 12 and the bottom case 14 could also be connected in a sealed way by welding or riveting. A side of the bottom case 14 corresponding to a front-half portion of the case 10 is disposed with six openings 143 that are spaced along a right-left direction. Each of the openings 143 is a rectangular opening. Each of the openings 143 communicates with the chamber 16. Left and right ends of the bottom case 14 corresponding to the back side of the case 10 are respectively provided with a liquid inlet 144 and a liquid outlet 145. The liquid inlet 144 and the liquid outlet 145 communicate with the chamber 16 respectively.

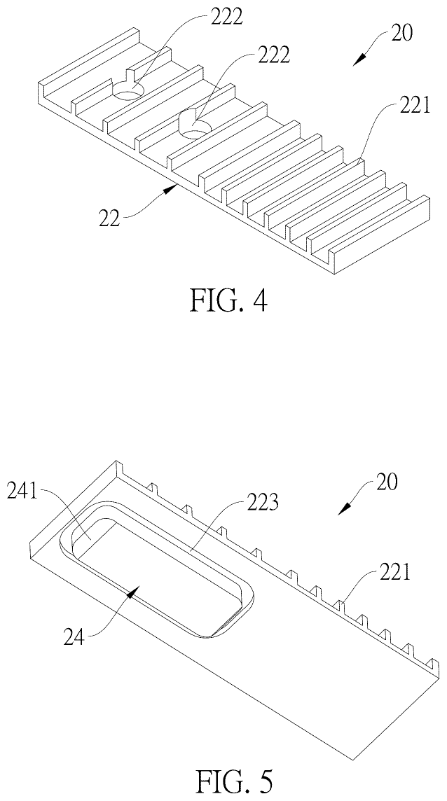

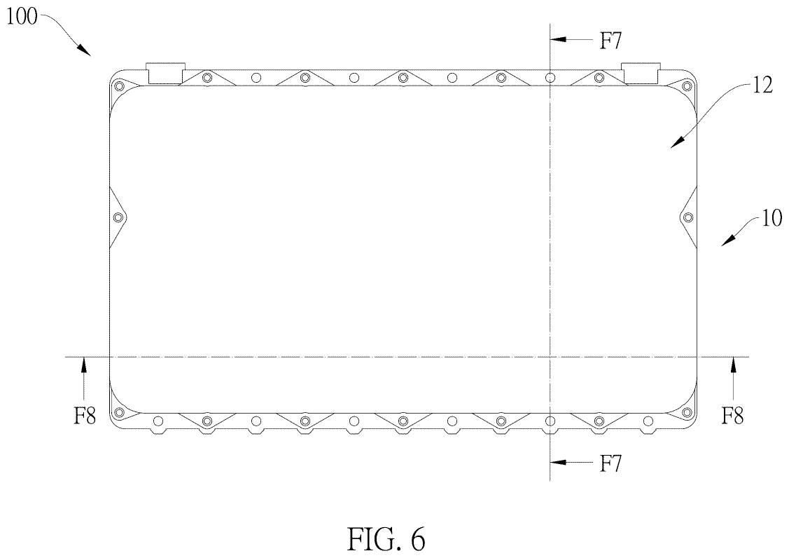

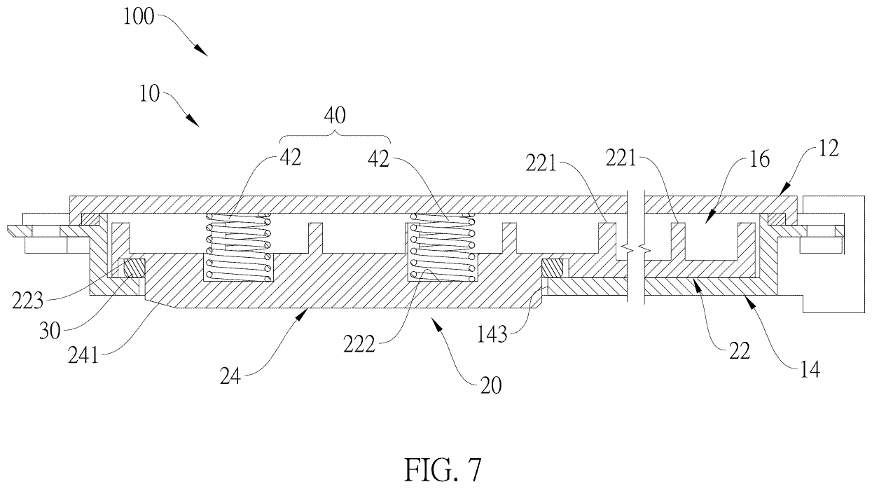

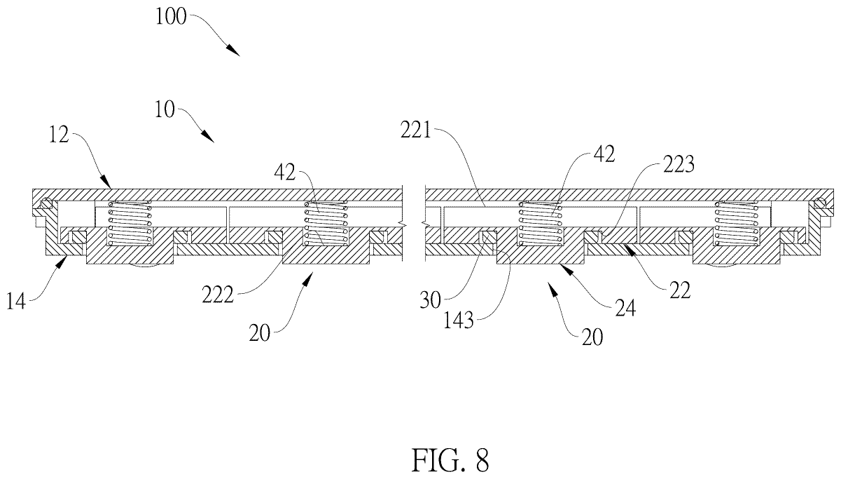

Referring to FIG. 4 to FIG. 5, and FIG. 6 to FIG. 8, the cooling fins 20 are spaced along the right-left direction and are arranged side by side in the chamber 16 of the case 10. Each of the cooling fins 20 has a substrate 22. A side of a front-half portion of the substrate 22 facing the opening 143 is connected to a thermal bump 24. A shape of a periphery of the thermal bump 24 matches with a shape of the corresponding opening 143.

The thermal bump 24 passes through the corresponding opening 143 and protrudes from a surface of the bottom case 14. A front side of a periphery of the thermal bump 24 has a guiding portion 241. In the first embodiment, the guiding portion 241 is a sloped surface. In other embodiments, the guiding portion 241 could also be an arc surface or a rounded corner. In addition, the guiding portion 241 could also be adjusted to be located on any side of the periphery of the thermal bump 24 as required. A side of the substrate 22 facing the chamber 16 is connected to a plurality of heat sinks 221. Another side of the front-half portion of the substrate 22 facing the chamber 16 has two spring grooves 222 that are spaced along a front-back direction. The substrate 22 further has a seal ring groove 223. The seal ring groove 223 is an annular groove and is adjacently connected to the thermal bump 24 to surround the periphery of the thermal bump 24.

Each of the first seal rings 30 is an annular elastomer and is used to seal a gap between each of the cooling fins 20 and a periphery of each of the openings 143. A side of each of the first seal rings 30 fits in the seal ring groove 223 of each of the cooling fins 20 and is in contact with each of the cooling fins 20. Another side of each of the first seal rings 30 is in contact with the periphery of each of the openings 143. Each of the first seal rings 30 is clamped by the seal ring groove 223 of each of the cooling fins 20 and the periphery of each of the openings 143. In the first embodiment, a length of each of the first seal rings 30 that is deformed due to clamping of the seal ring groove 223 of each of the cooling fins 20 and the periphery of each of the openings 143 is greater than a length of the thermal bump 24 of each of the cooling fins 20 that protrudes from each of the openings 143. In this way, when one of the thermal bumps 24 of the cooling fins 20 is pushed and shrunk into the corresponding opening 143, the first seal ring 30 located therein remains clamped by the seal ring groove 223 of the corresponding cooling fin 20 and the periphery of the corresponding opening 143, so that the first seal ring 30 could still provide sealing and prevent leakage.

Each of the elastic assemblies 40 includes two springs 42. A side of each of the springs 42 corresponding to each of the cooling fins 20 is contained in each of the spring grooves 222, so that the side of each of the springs 42 is in contact with each of the cooling fins 20. Another side of each of the springs 42 abuts against an inner wall of the top case 12 to be fixed in the case 10. When the thermal bump 24 of each of the cooling fins 20 is pushed and each of the cooling fins 20 is correspondingly moved towards the chamber 16 to deform each of the elastic assemblies 40, each of the elastic assemblies 40 generates a restoring force that returns the corresponding cooling fin 20 to an original position. The restoring force is greater than a rebound force generated by a deformation of each of the first seal rings 30 that is clamped by the seal ring groove 223 of each of the cooling fins 20 and the periphery of each of the openings 143. In this way, each of the cooling fins 20 would not move towards the chamber 16 unless each of the cooling fins 20 is pushed by an external force.

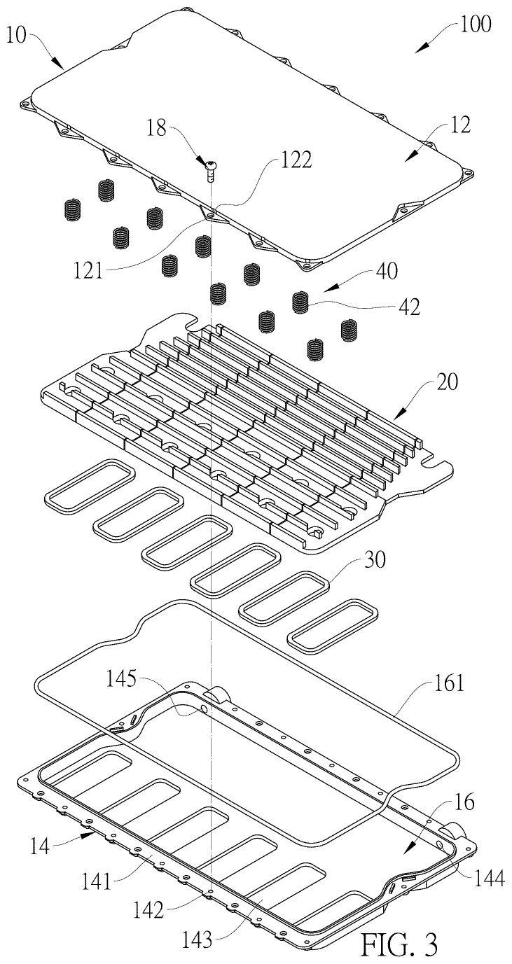

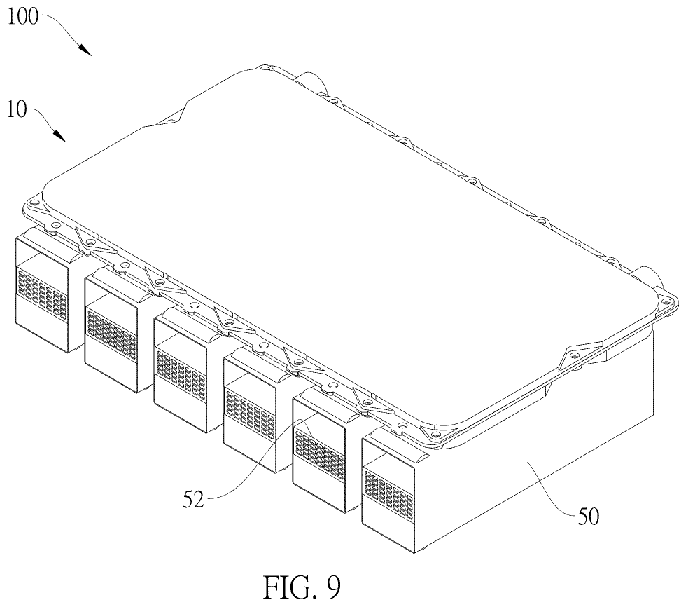

Referring to FIG. 3 and FIG. 9 to FIG. 11, when the liquid-cooling heat dissipation device 100 of the first embodiment according to the present invention is used, an optical communication device has six sockets 50 matching the number of the cooling fins 20 in the case 10 and the case 10 of the liquid-cooling heat dissipation device 100 is disposed on the six sockets 50 of the optical communication device. More specifically, the bottom case 14 is fixed on the sockets 50.

The sockets 50 are spaced along the right-left direction. A front of each of the sockets 50 has a jack 52. A side of each of the sockets 50 facing the case 10 has an insertion hole 54. The thermal bump 24 of each of the cooling fins 20 of the liquid-cooling heat dissipation device 100 passes through the corresponding insertion hole 54 and extends into the corresponding socket 50. The guiding portion 241 of each of the thermal bumps 24 is located on a side of each of the thermal bumps 24 facing each of the jacks 52. At the same time, the liquid inlet 144 of the case 10 and the liquid outlet 145 of the case 10 are connected to a liquid pipeline for heat dissipation, so that the chamber 16 within the case 10 is filled with a liquid for heat dissipation. The substrate 22 of each of the cooling fins 20 and the heat sinks 221 connected the substrate 22 are in contact with the liquid for heat dissipation within the chamber 16.

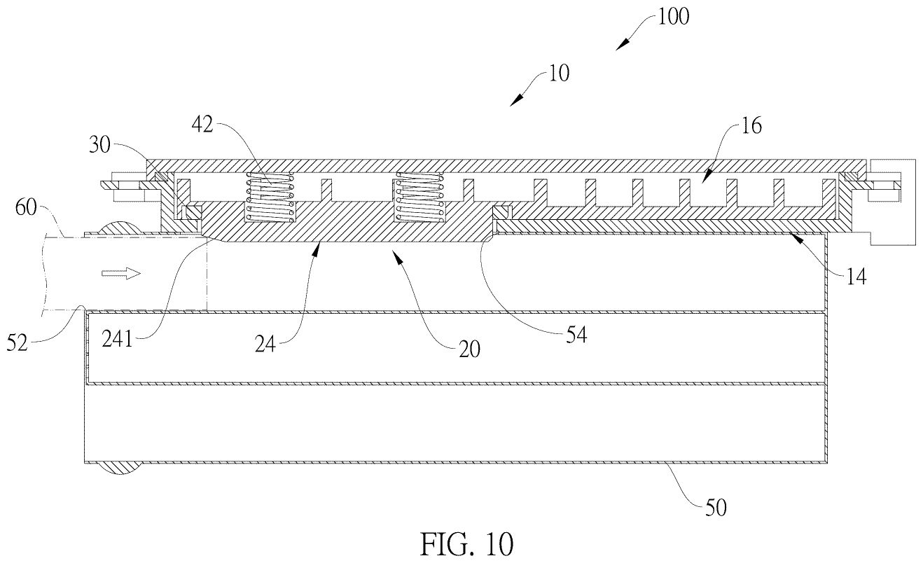

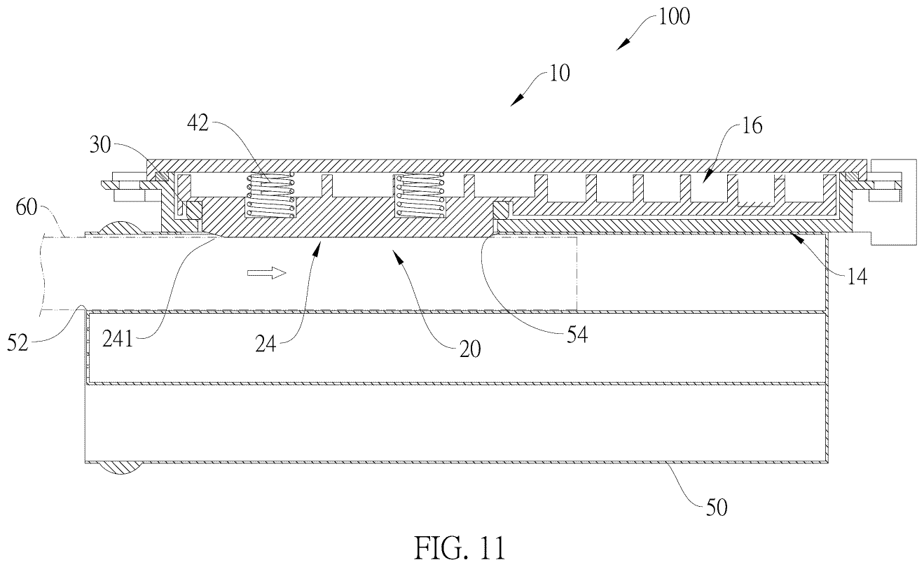

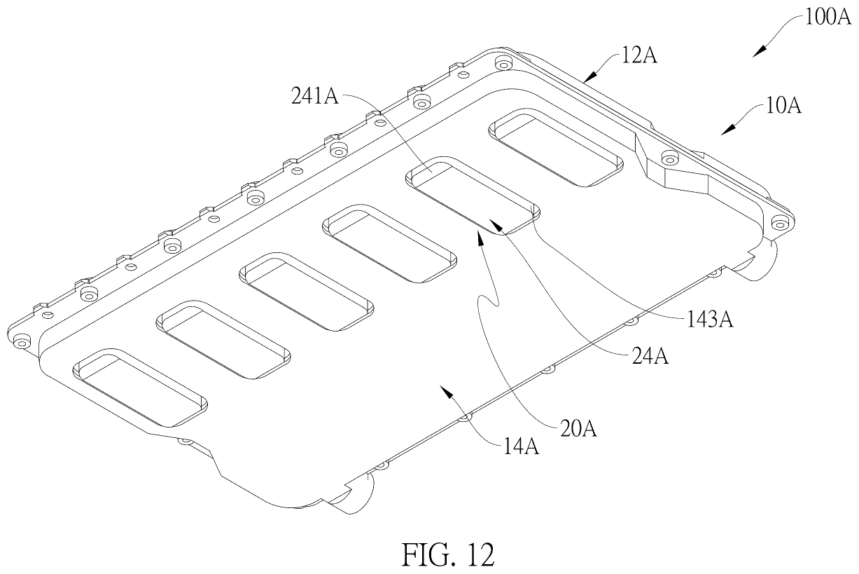

Referring to FIG. 10 to FIG. 11, when a small form-factor pluggable 60 is plugged into the jack 52 of any one of the sockets 50, the small form-factor pluggable 60 would first contact the guiding portion 241 of the thermal bump 24 of the cooling fin 20 extending into the socket 50. By the guidance of the guiding portion 241, the cooling fin 20 having the thermal bump 24 is pushed up when the small form-factor pluggable 60 is plugged into the socket 50. After the cooling fin 20 is pushed up by the small form-factor pluggable 60, the restoring force generated by the two springs 42 of the elastic assembly 40 corresponding to the cooling fin 20 is applied on the cooling fin 20, so that the thermal bump 24 of the cooling fin 20 could remain attaching to the small form-factor pluggable 60 tightly.

By the small form-factor pluggable 60 being in contact with the thermal bump 24 of the cooling fin 20, a heat generated during an operation of the small form-factor pluggable 60 is conducted to the liquid for heat dissipation in the chamber 16 of the case 10 through the cooling fin 20. With a circular process that the liquid for heat dissipation flows into the case 10 through the liquid inlet 144 of the case 10 and is discharged from the case 10 through the liquid outlet 145 of the case 10 for cooling, the heat conducted to the liquid for heat dissipation is removed, so that the small form-factor pluggable 60 contacting the cooling fin 20 could be cooled down.

When the small form-factor pluggable 60 is unplugged from the socket 50, the cooling fin 20 corresponding to the socket 50 is no longer pushed up by the small form-factor pluggable 60, so that the cooling fin 20 subjected to the restoring force of the two springs 42 would return to the original position at which the thermal bump 24 passes through the corresponding insertion hole 54 and extends into the socket 50. As the length of each of the first seal rings 30 that is deformed due to clamping of each of the cooling fins 20 and the periphery of each of the openings 143 is greater than the length of the thermal bump 24 of each of the cooling fins 20 that protrudes from each of the openings 143, each of the first seal rings 30 could seal between each of the cooling fins 20 and the periphery of each of the openings 143 of the case 10 to prevent leakage when each of the cooling fins 20 is lifted or declined.

In the first embodiment according to the present invention, the top case 12 of the case 10 is the plate, the bottom case 14 of the case 10 is the tray, and the top case 12 and the bottom case 14 are connected to each other in a sealed way; in other embodiments, according to the needs, the top case 12 could be a cover, the bottom case 14 could be a plate, and the top case 12 and the bottom case 14 are connected to each other in a sealed way to form the case 10. In addition, in the first embodiment, the number of the openings 143 of the bottom case 14 is six, but not limited thereto; the number of the opening 143 could be one, two, three, or more, and the number of the cooling fin 20, the number of the first seal ring 30, and the number of the elastic assembly 40 correspond to the number of the opening 143.

Besides the number of the above mentioned openings 143, the position of the openings 143 disposed on the case 10 could be changed according to the needs. The side of the substrate 22 of each of the cooling fins 20 facing the chamber 16 could be provided without the plurality of heat sinks 221. The number of the spring groove 222 of the substrate 22 could be one, three, or more, and the number of the spring 42 of each of the elastic assemblies 40 changes with the number of the spring groove 222. In addition, as the position of the openings 143 disposed on the case 10 is changed, the position where the thermal bump 24 of each of the cooling fins 20 is connected to the substrate 22 is not limited to the front-half portion of each of the cooling fins 20; the thermal bump 24 of each of the cooling fins 20 could be connected to a middle portion of the substrate 22 or a back-half portion of the substrate 22.

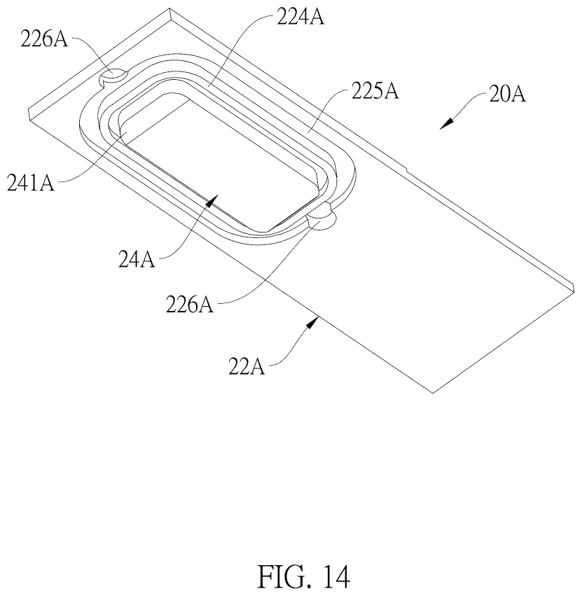

As illustrated in FIG. 12 to FIG. 14, a liquid-cooling heat dissipation device 100A of a second embodiment according to the present invention includes a case 10A, six cooling fins 20A, six first seal rings 30A matching the number of the cooling fins 20A, and six elastic assemblies 40A matching the number of the cooling fins 20A.

The case 10A is a flat shell and has a front side, a back side, a left side, a right side, a top side, a bottom side in terms of direction. The case 10A includes a top case 12A and a bottom case 14A. The top case 12A and the bottom case 14A are connected to each other in a sealed way by a plurality of fixing elements through screwing, thereby forming a chamber 16A within the case 10A. In other embodiments, the top case 12A and the bottom case 14A could also be connected in a sealed way by welding or riveting. A side of the bottom case 14A corresponding to a front-half portion of the case 10A is disposed with six openings 143A that are spaced along a right-left direction. Each of the openings 143A communicates with the chamber 16A. Left and right ends of the bottom case 14A corresponding to the back side of the case 10A are respectively provided with a liquid inlet 144A and a liquid outlet 145A. The liquid inlet 144A and the liquid outlet 145A communicate with the chamber 16A respectively.

Two portions of the bottom case 14A corresponding to two opposite sides of a periphery of each of the openings 143A are respectively connected to two sleeves 146A. In the second embodiment, the two portions of the bottom case 14A corresponding to front and back sides of the periphery of each of the openings 143A are connected to the two sleeves 146A. The two sleeves 146A extend into the chamber 16 and have a screw hole 147A respectively. The periphery of each of the openings 143A surrounds to form a protruding ring 148A. The protruding ring 148A has a protruding edge portion 1481A and a protruding ring portion 1482A. The protruding edge portion 1481A is annular. The protruding ring portion 1482A is annular and is adjacently connected to a periphery of the protruding edge portion 1481A. A portion of an inner side of each of the sleeves 146A around each of the openings 143A is connected to a periphery of the protruding ring portion 1482A.

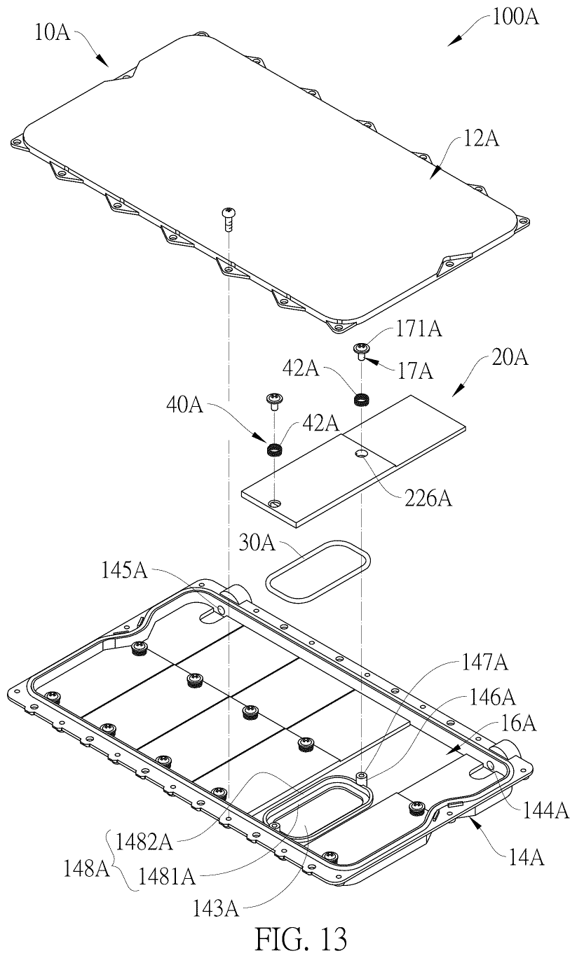

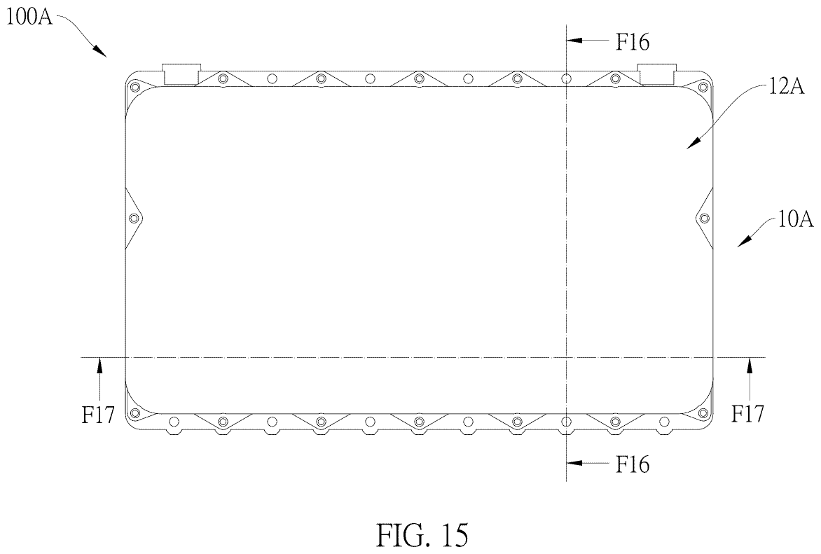

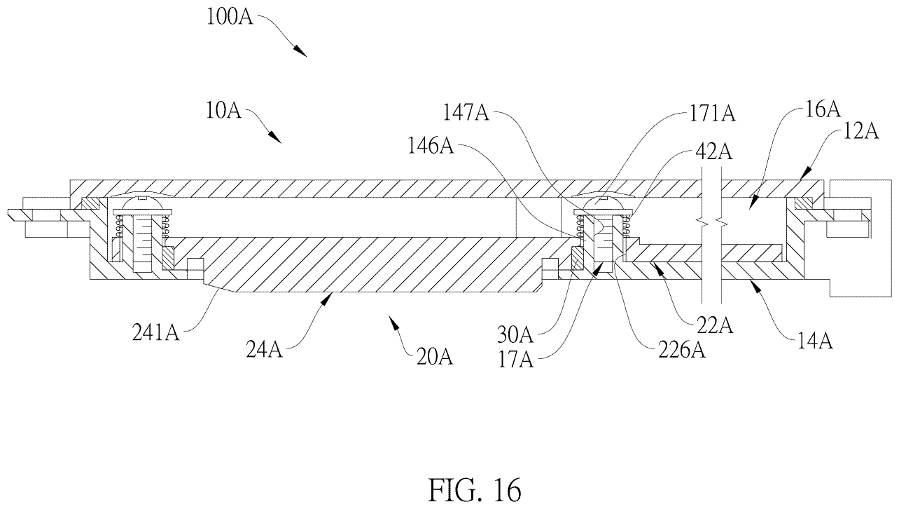

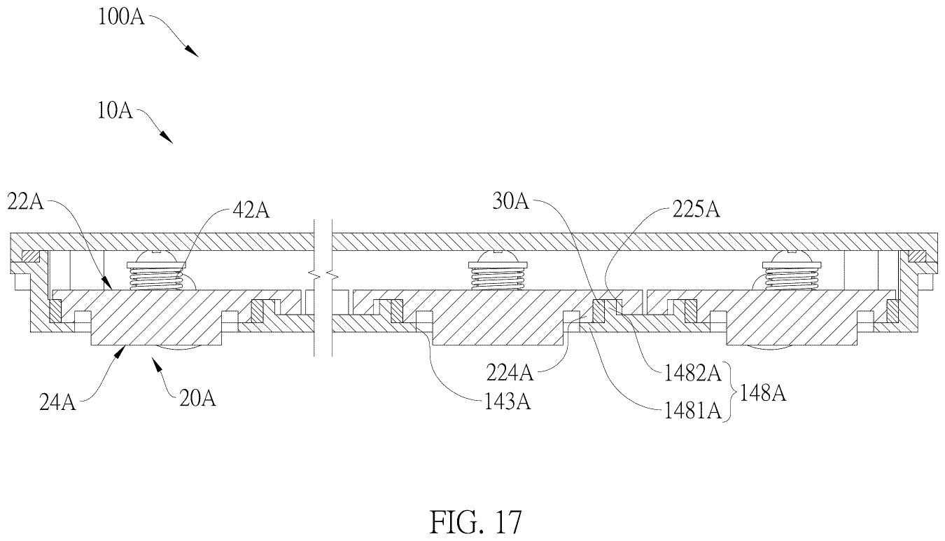

Referring to FIG. 13 to FIG. 17, the cooling fins 20A are spaced along the right-left direction and are arranged side by side in the chamber 16A of the case 10A. Each of the cooling fins 20A has a substrate 22A. A side of a front-half portion of the substrate 22A facing the opening 143A is connected to a thermal bump 24A. The thermal bump 24A passes through the corresponding opening 143A and protrudes from a surface of the bottom case 14A. A front side of a periphery of the thermal bump 24A has a guiding portion 241A. The guiding portion 241A is a sloped surface. In other embodiments, the guiding portion 241A could also be an arc surface or a rounded corner. In addition, the guiding portion 241A could also be adjusted to be located on any side of the periphery of the thermal bump 24A as required.

The substrate 22A has a surrounding portion 224A and a surrounding groove 225A. The surrounding portion 224A is an annular portion. The surrounding portion 224A is adjacently connected to the periphery of the thermal bump 24A. The surrounding groove 225A is an annular groove. The surrounding groove 225A is adjacently connected to a periphery of the surrounding portion 224A. The substrate 22A of each of the cooling fins 20A has two sleeving holes 226A matching the two sleeves 146A around each of the openings 143A. The two sleeving holes 226A are respectively located on front and back sides of the periphery of the thermal bump 24A. A portion of an inner side of each of the two sleeving holes 226A penetrates the surrounding groove 225A. When each of the cooling fins 20A is disposed on each of the openings 143A of the case 10A, the surrounding portion 224A of each of the cooling fins 20A abuts against the protruding edge portion 1481A of each of the protruding rings 148A and the annular protruding ring portion 1482A of each of the protruding rings 148A extends into the surrounding groove 225A of each of the cooling fins 20A. At the same time, the surrounding portion 224A and the protruding ring portion 1482A are spaced and each of the sleeving holes 226A fits around each of the sleeves 146A.

Each of the first seal rings 30A is an annular elastomer and is used to seal a gap between each of the cooling fins 20A and the periphery of each of the openings 143A. Each of the first seal rings 30A is clamped between the surrounding portion 224A of each of the cooling fins 20A and the protruding ring portion 1481A of the periphery of each of the openings 143A, so that a side of each of the first seal rings 30A is in contact with the surrounding portion 224A of each of the cooling fins 20A and another side of each of the first seal rings 30A is in contact with the periphery of each of the openings 143A.

Each of the elastic assemblies 40A includes two springs 42A. Each of the springs 42A fits around each of the sleeves 146A. The screw hole 147A of each of the sleeves 146A of the case 10A is screwed by a screw 17A. The screw 17A has a head portion 171A. An end of each of the springs 42A abuts against a periphery of each of the sleeving holes 226A; that is, the end of each of the springs 42A abuts against substrate 22A of each of the cooling fins 20A. Another end of each of the springs 42A abuts against the head portion 171A of each of the screws 17A. In this way, the side of each of the springs 42A is in contact with each of the cooling fins 20A. The another side of each of the springs 42A is relatively fixed to the case 10A. When the thermal bump 24A of each of the cooling fins 20A is pushed and each of the cooling fins 20A is correspondingly moved towards the chamber 16A to deform each of the elastic assemblies 40A, each of the elastic assemblies 40A generates a restoring force that returns the corresponding cooling fin 20A to an original position.

The liquid-cooling heat dissipation device 100A of the second embodiment according to the present invention is used in the same way as the liquid-cooling heat dissipation device 100 of the first embodiment. An optical communication device has six sockets and the case 10A of the liquid-cooling heat dissipation device 100A is fixed on the six sockets of the optical communication device. The liquid inlet 144A of the case 10A and the liquid outlet 145A of the case 10A are connected to a liquid pipeline for heat dissipation at the same time, so that the chamber 16A within the case 10A is filled with a liquid for heat dissipation and the substrate 22A of each of the cooling fins 20A is in contact with the liquid for heat dissipation within the chamber 16A. The operation way and the effect of the second embodiment are the same as that of the first embodiment and are not repeated here.

In the second embodiment according to the present invention, the number of the openings 143A of the bottom case 14A of the case 10A is six, but not limited thereto; the number of the opening 143A could be one, two, three, or more, and the number of the cooling fin 20A, the number of the first seal ring 30A, and the number of the elastic assembly 40A correspond to the number of the opening 143. In addition, the position of the openings 143A disposed on the case 10A could be changed according to the needs. As the position of the openings 143A disposed on the case 10A is changed, the position where the thermal bump 24A of each of the cooling fins 20A is connected to the substrate 22A is not limited to the front-half portion of each of the cooling fins 20A; the thermal bump 24A of each of the cooling fins 20A could be connected to a middle portion of the substrate 22A or a back-half portion of the substrate 22A. Furthermore, a side of the substrate 22A of each of the cooling fins 20A facing the chamber 16A could be connected to a plurality of heat sinks.

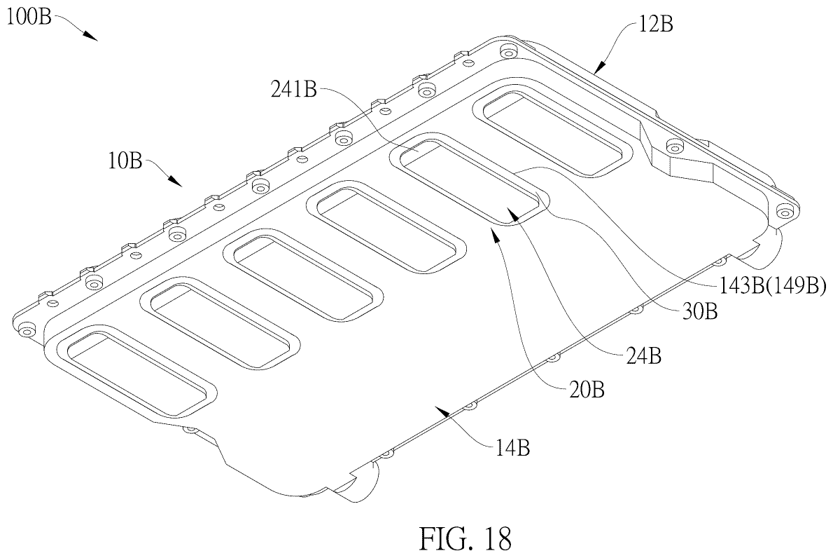

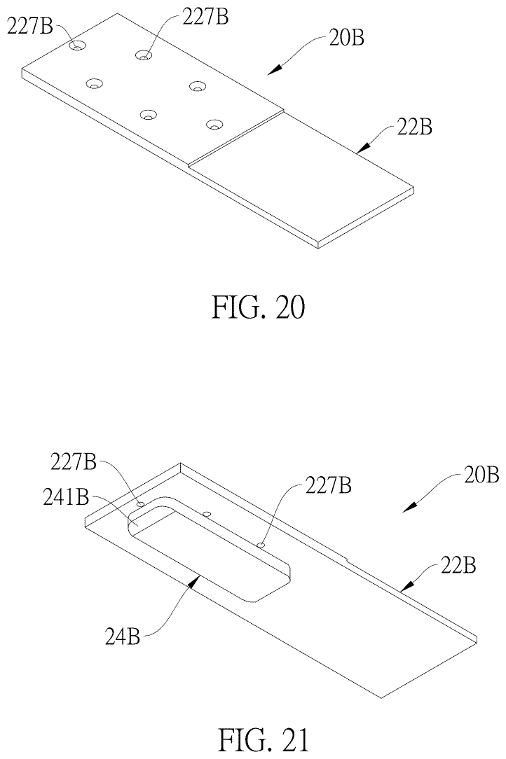

As illustrated in FIG. 18 to FIG. 21, a liquid-cooling heat dissipation device 100B of a third embodiment according to the present invention includes a case 10B, six cooling fins 20B, six first seal rings 30B matching the number of the cooling fins 20B, and six elastic assemblies 40B matching the number of the cooling fins 20B.

The case 10B is a flat shell and has a front side, a back side, a left side, a right side, a top side, a bottom side in terms of direction. The case 10B includes a top case 12B and a bottom case 14B. The top case 12B and the bottom case 14B are connected to each other in a sealed way by a plurality of fixing elements through screwing, thereby forming a chamber 16B within the case 10B. In other embodiments, the top case 12B and the bottom case 14B could also be connected in a sealed way by welding or riveting. A side of the bottom case 14B corresponding to a front-half portion of the case 10B is disposed with six openings 143B that are spaced along a right-left direction. Each of the openings 143B is rectangular substantially and communicates with the chamber 16B. Left and right ends of the bottom case 14B corresponding to the back side of the case 10B are respectively provided with a liquid inlet 144B and a liquid outlet 145B. The liquid inlet 144B and the liquid outlet 145B communicate with the chamber 16B respectively.

A periphery of each of the openings 143B of the bottom case 14B has an annular side wall 149B. The annular side wall 149B is a rectangular and annular surface. A width of a side of the annular side wall 149B, which is adjacently connected to the chamber 16B, is less than a width of another side of the annular side wall 149B, which is away from the chamber 16B.

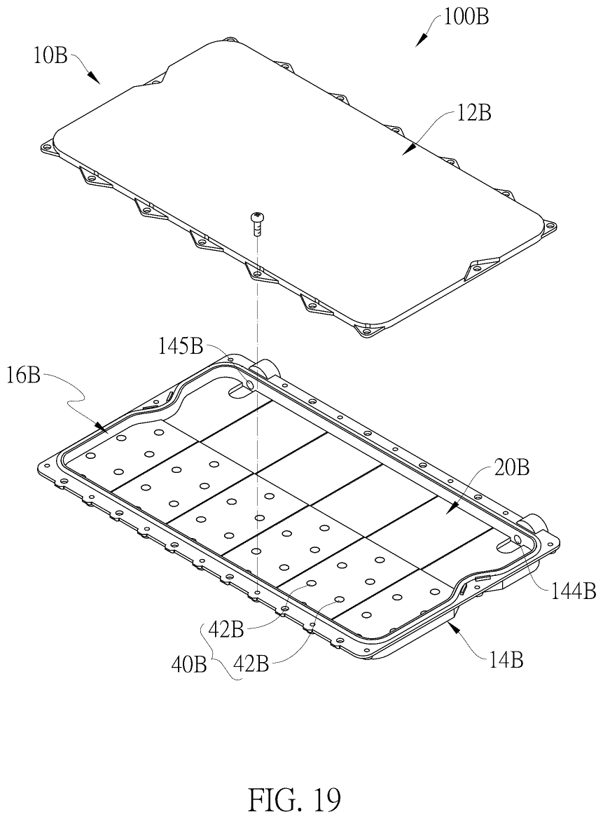

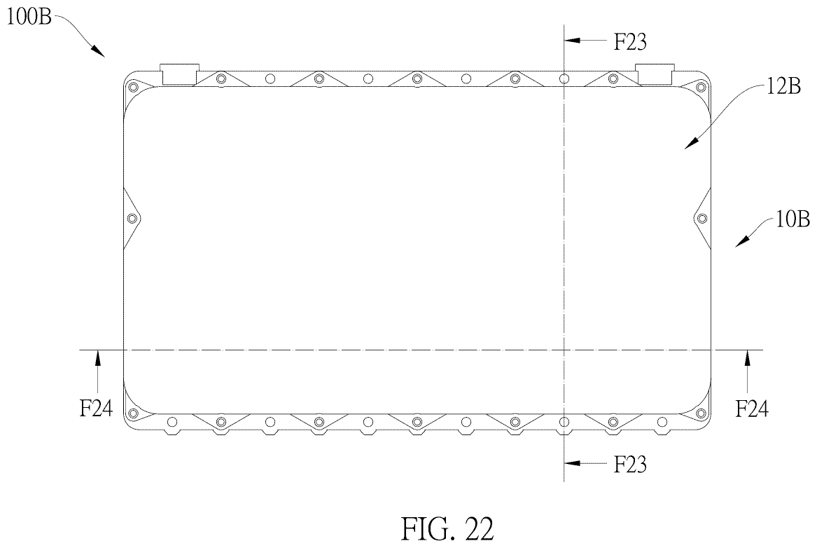

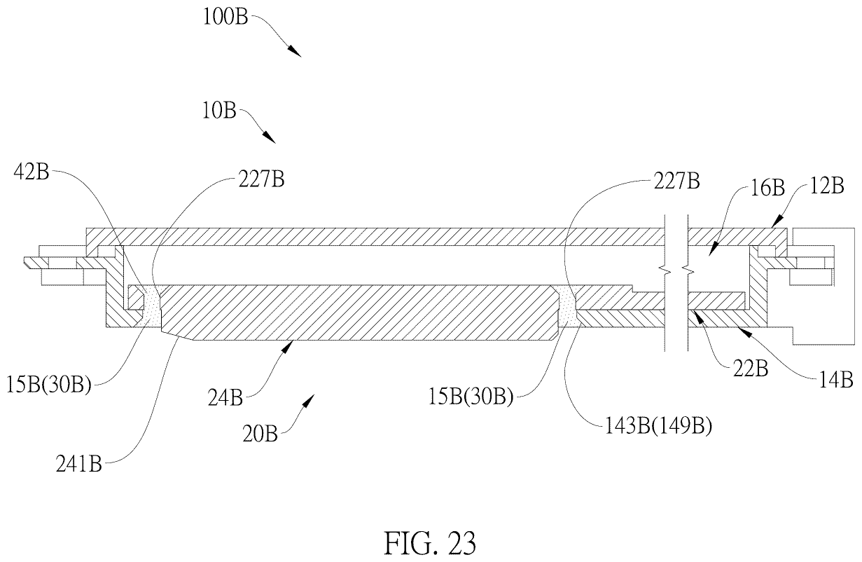

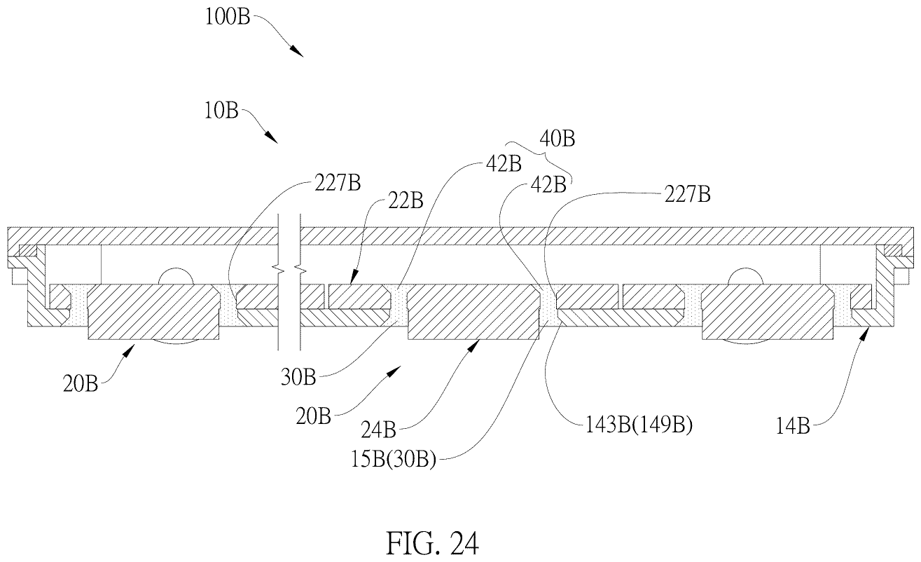

Referring to FIG. 19 to FIG. 24, the cooling fins 20B are spaced along the right-left direction and are arranged side by side in the chamber 16B of the case 10B. Each of the cooling fins 20B has a substrate 22B. A side of a front-half portion of the substrate 22B facing each of the openings 143B is connected to a thermal bump 24B. The substrate 22B has a plurality fitting holes 227B arranged around the substrate 22B. A bottom end of each of the fitting holes 227B is adjacently connected to a periphery of the thermal bump 24B. A width of the bottom end of each of the fitting holes 227B, which is adjacently connected to the thermal bump 24B, is greater than a width of a top end of each of the fitting holes 227B, which is away from the thermal bump 24B. In the third embodiment, each of the fitting holes 227B is a tapered hole. In other embodiments, each of the fitting holes 227B could also be a counterbore.

A shape of the periphery of the thermal bump 24B is smaller than a shape of the corresponding opening of the bottom case 143B. The thermal bump 24B passes through a middle of the corresponding opening 143B and protrudes from a surface of the bottom case 14B, so that the annular side wall 149B and a peripheral surface of the thermal bump 24B are spaced to form an annular space 15B. The bottom end of each of the fitting holes 227B communicates with the annular space 15B. A front side of the periphery of the thermal bump 24B has a guiding portion 241B. In other embodiments, the guiding portion 241B could also be adjusted to be located on any side of the periphery of the thermal bump 24B as required.

Each of the first seal rings 30B is an annular elastomer and is used to seal a gap between each of the cooling fins 20B and the periphery of each of the openings 143B. In the third embodiment, each of the first seal rings 30B is disposed between the thermal bump 24B of each of the cooling fins 20B and the annular side wall 149B of the periphery of each of the openings 143B, and a shape of each of the first seal rings 30B is the same as a shape of the annular space 15B, so that a side of an inner periphery of each of the first seal rings 30B is in contact with the peripheral surface of the thermal bump 24B of each of the cooling fins 20B, and another side of an outer periphery of each of the first seal rings 30B is in contact with the annular side wall 149B of the periphery of each of the openings 143B.

Each of the elastic assemblies 40B includes a plurality of elastic blocks 42B. A shape of each of the elastic blocks 42B is the same as a shape of each of the fitting holes 227B. Each of the elastic blocks 42B fits in each of the fitting holes 227B. An end of each of the elastic blocks 42B facing each of the first seal rings 30B is connected to each of the first seal rings 30B to become a single unit. In the third embodiment, a material of each of the elastic blocks 42B is the same as a material of each of the first seal rings 30B and is elastic rubber. In other embodiments, the material of each of the elastic blocks 42B and the material of each of the first seal rings 30B could be elastic plastic. A side of each of elastic blocks 42B connected to each of the first seal rings 30B is relatively fixed to the case 10B. When the thermal bump 24B of each of the cooling fins 20B is pushed and each of the cooling fins 20B is correspondingly moved towards the chamber 16B to deform each of the elastic assemblies 40B, each of the elastic assemblies 40B generates a restoring force that returns the corresponding cooling fin 20B to an original position.

The liquid-cooling heat dissipation device 100B of the third embodiment according to the present invention is used in the same way as the liquid-cooling heat dissipation device 100 of the first embodiment and the liquid-cooling heat dissipation device 100A of the second embodiment. An optical communication device has six sockets and the case 10B of the liquid-cooling heat dissipation device 100B is fixed on the six sockets of the optical communication device. The liquid inlet 144B of the case 10B and the liquid outlet 145B of the case 10B are connected to a liquid pipeline for heat dissipation at the same time, so that the chamber 16B within the case 10B is filled with a liquid for heat dissipation and the substrate 22B of each of the cooling fins 20B is in contact with the liquid for heat dissipation within the chamber 16B. The operation way and the effect of the third embodiment is the same as that of the first embodiment and that of the second embodiment and are not repeated here.

In the third embodiment according to the present invention, the number of the openings 143B of the bottom case 14B of the case 10B is six, but not limited thereto; the number of the opening 143B could be one, two, three, or more, and the number of the cooling fin 20A, the number of the first seal ring 30A, and the number of the elastic assembly 40A correspond to the number of the opening 143. In addition, the position of the openings 143B disposed on the case 10B could be changed according to the needs. As the position of the openings 143B disposed on the case 10B is changed, the position where the thermal bump 24B of each of the cooling fins 20B is connected to the substrate 22B is not limited to the front-half portion of each of the cooling fins 20B; the thermal bump 24B of each of the cooling fins 20B could be connected to a middle portion of the substrate 22B or a back-half portion of the substrate 22B. Furthermore, a side of the substrate 22B of each of the cooling fins 20B facing the chamber 16B could be connected to a plurality of heat sinks.

It must be pointed out that the embodiments described above are only some preferred embodiments of the present invention. All equivalent structures which employ the concepts disclosed in this specification and the appended claims should fall within the scope of the present invention.

What is claimed is:

1. A liquid-cooling heat dissipation device, comprising:
a case comprising a bottom case and a top case, wherein the bottom case and the top case are connected to each other in a sealed way to form a chamber within the case; the case further has a liquid inlet and a liquid outlet; the liquid inlet and the liquid outlet communicate with the chamber respectively; the bottom case has at least one opening; the at least one opening communicates with the chamber;
at least one cooling fin disposed in the chamber and having a thermal bump, wherein the thermal bump of the at least one cooling fin correspondingly passes through the at least one opening and protrudes from the bottom case; a side of a periphery of the thermal bump has a guiding portion;
at least one first seal ring, wherein a side of the at least one first seal ring is in contact with the at least one cooling fin; another side of the at least one first seal ring is in contact with a periphery of the at least one opening; the at least one first seal ring seals between a periphery of the at least one cooling fin and the periphery of the at least one opening; and
at least one elastic assembly, wherein an end of the at least one elastic assembly is fixed to the case and another end of the at least one elastic assembly is in contact with the at least one cooling fin; when the thermal bump of the at least one cooling fin is pushed and the at least one cooling fin is correspondingly moved towards the chamber to deform the at least one elastic assembly, the at least one elastic assembly generates a restoring force that correspondingly returns the at least one cooling fin to an original position.

2. The liquid-cooling heat dissipation device as claimed in claim 1, wherein the at least one cooling fin comprises a substrate; the thermal bump is connected to a side of the substrate facing the at least one opening; the substrate has a seal ring groove which surrounds the periphery of the thermal bump; the side of the at least one first seal ring fits in the seal ring groove and is in contact with the at least one cooling fin; the at least one first seal ring is an annular elastomer and is clamped by the seal ring groove and the periphery of the at least one opening.

3. The liquid-cooling heat dissipation device as claimed in claim 2, wherein a perimeter of the top case has a periphery; the periphery of the top case has a plurality of fixing holes arranged around the periphery of the top case; a perimeter of the bottom case has a periphery; the periphery of the bottom case has a plurality of fixing holes arranged around the periphery of the bottom case; a second seal ring is clamped between the periphery of the top case and the periphery of the bottom case; a plurality of fixing elements respectively pass through the plurality of fixing holes of the top case on the periphery of the top case and the plurality of fixing holes of the bottom case on the periphery of the bottom case to fix the top case and the bottom case.

4. The liquid-cooling heat dissipation device as claimed in claim 3, wherein the substrate of the at least one cooling fin has a plurality of spring grooves; the at least one elastic assembly comprises a plurality of springs; a side of each of the plurality of springs is contained in each of the plurality of spring grooves and another side of each of the plurality of springs abuts against the top case.

5. The liquid-cooling heat dissipation device as claimed in claim 4, wherein another side of the substrate of the at least one cooling fin facing the chamber is connected to a plurality of heat sinks.

6. The liquid-cooling heat dissipation device as claimed in claim 1, wherein the at least one cooling fin comprises a substrate; the thermal bump is connected to the substrate; two portions of the bottom case corresponding to two opposite sides of the periphery of the at least one opening are connected to two sleeves; the two sleeves extend into the chamber; the substrate of the at least one cooling fin has two sleeving holes; the two sleeving holes are located on two opposite sides of the periphery of the thermal bump; each of the two sleeving holes fits around each of the two sleeves; two screws are respectively screwed into the two sleeves; each of the two screws has a head portion; the at least one elastic assembly comprises two springs; each of the two springs fits around each of the two sleeves; an end of each of the two springs abuts against a periphery of each of the two sleeving holes, and another end of each of the two springs abuts against the head portion of each of the two screws.

7. The liquid-cooling heat dissipation device as claimed in claim 6, wherein the substrate has a surrounding portion and a surrounding groove; the surrounding portion is adjacently connected to the periphery of the thermal bump; the surrounding groove is adjacently connected to a periphery of the surrounding portion; the periphery of the at least one opening forms a protruding ring; the protruding ring has a protruding edge portion and a protruding ring portion adjacently connected to a periphery of the protruding edge portion; the surrounding portion abuts against the protruding edge portion; the protruding ring portion extends into the surrounding groove; the at least one first seal ring is an annular elastomer and is clamped between the surrounding portion and the protruding ring portion, so that the side of the at least one first seal ring is in contact with the at least one cooling fin and the another side of the at least one first seal ring is in contact with the periphery of the at least one opening.

8. The liquid-cooling heat dissipation device as claimed in claim 7, wherein a portion of each of the two sleeving holes of the at least one cooling fin penetrates the surrounding groove; a portion of each of the two sleeves of the periphery of the at least one opening is connected to a periphery of the protruding ring portion.

9. The liquid-cooling heat dissipation device as claimed in claim 1, wherein the at least one cooling fin comprises a substrate and the thermal bump is connected to the substrate; the substrate has a plurality fitting holes arranged around the substrate; the plurality of fitting holes are adjacently connected to the periphery of the thermal bump; a width of an end of each of the plurality fitting holes, which is adjacently connected to the thermal bump, is greater than a width of another end of each of the plurality fitting holes, which is away from the thermal bump; the periphery of the at least one opening has an annular side wall; a width of a side of the annular side wall, which is adjacently connected to the chamber, is less than a width of another side of the annular side wall, which is away from the chamber; the annular side wall and a peripheral surface of the thermal bump are spaced; the at least one first seal ring is an annular body which is elastic and a side of the at least one first seal ring is in contact with the annular side wall and another side of the at least one first seal ring is in contact with the peripheral surface of the thermal bump; the at least one elastic assembly comprises a plurality of elastic blocks; each of the plurality of elastic blocks fits in each of the plurality of fitting holes; an end of each of the plurality of elastic blocks facing the at least one first seal ring is connected to the at least one first seal ring to become a single unit.

10. The liquid-cooling heat dissipation device as claimed in claim 9, wherein each of the plurality of fitting holes is a tapered hole.
